(19) United States
(12) Patent Application Publication
(10) Pub. No.: US 2021/0023872 A1
(43) Pub. Date: Jan. 28, 2021

(54) MODULAR WRITING SURFACE

(71) Applicant: SESH Corp., Topanga, CA (US)

(72) Inventors: Cauri Jaye, Los Angeles, CA (US); David Harley Dorfman, Santa Monica, CA (US)

(21) Appl. No.: 16/936,964

(22) Filed: Jul. 23, 2020

Related U.S. Application Data
(60) Provisional application No. 62/879,331, filed on Jul. 26, 2019.

(51) Int. Cl. B43L 1/00; F16B 2/00; F16B 5/00; F16B 1/00; G06F 1/16; H05K 5/00

(52) U.S. Cl. CPC B43L 1/008; F16B 2/005; F16B 5/0004; F16B 1/00; F16B 2001/0035; G06F 1/1601; H05K 5/0017; H05K 5/0021; B43L 1/004

(57) ABSTRACT

A plurality of modular tiles can be connected to form a writing surface. The modular tiles are shaped to enable multiple tiles to be connected to form a continuous surface (e.g., hexagonal, rectangular, etc.). Each modular tile has a writing element and a friction element opposite the writing surface to prevent the modular tile form slipping when placed on a horizontal surface. The modular tiles may also have a coupling mechanism, such as magnets with appropriate polarization, allowing the modular tiles to be coupled to one another to form a large surface and then be detached for simpler storage of the modular tiles. The modular tiles may further include lights, displays, or additional electronics to allow a connected computing device to display on the writing surface.

### CROSS-REFERENCE TO RELATED APPLICATIONS

This application claims the benefit of U.S. Provisional Application No. 62/879,331, filed Jul. 26, 2019, which is incorporated by reference in its entirety.

### BACKGROUND

Conventional writing surfaces and electronic displays have predetermined dimensions, limiting options for end-users. For example, a user is unable to increase a display area available for presenting content via a display device without obtaining an additional display device or a different, larger, display device. Similarly, a user is unable to increase dimensions of a writing surface, such as a whiteboard, without obtaining an additional writing surface or obtaining a different, larger, writing surface. This prevents users from easily adjusting dimensions of a display device or of a writing surface to accommodate changes in content to be presented or changes in available physical space.

### SUMMARY

A plurality of modular tiles can be connected to form a writing surface. The tiles are shaped to enable multiple tiles to be connected to form a continuous surface. For example, each tile is hexagonal, while in another example each tile is rectangular.

Each tile has a writing element on one side and a friction element on a side opposite the writing element, which prevents the tile from slipping or otherwise moving on a surface on which the tile is placed. In various embodiments the surface is a horizontal surface on which the tile is placed, while in other embodiments the surface on which the tile is placed is a vertical surface. The writing element comprises one or more materials in various embodiments. For example, the writing element is a glass surface with paint on a surface of the tile opposite the friction element. Each tile may also include one or more coupling mechanisms allowing a tile to be connected to another tile to form a larger surface, while allowing the tiles to be detached for easier storage. In various embodiments, a tile includes magnets having appropriate polarization along one or more edges, allowing an edge of the tile to be coupled an edge of another tile. The tiles may further include lights, displays, or additional electronics to allow computing device coupled to one or more of the tiles to display content via one or more of the tiles.

### BRIEF DESCRIPTION OF THE DRAWINGS

FIG. 1 is an example of a writing surface comprising a plurality of modular tiles coupled to each other, in accordance with an embodiment.

FIG. 2 is a side cross sectional view of a modular tile in accordance with an embodiment.

FIG. 3 is a side cross sectional view of an alternative implementation of a modular tile in accordance with an embodiment.

FIG. 4 is a system environment for modular tiles including an electronic display, in accordance with an embodiment.

The figures depict various embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

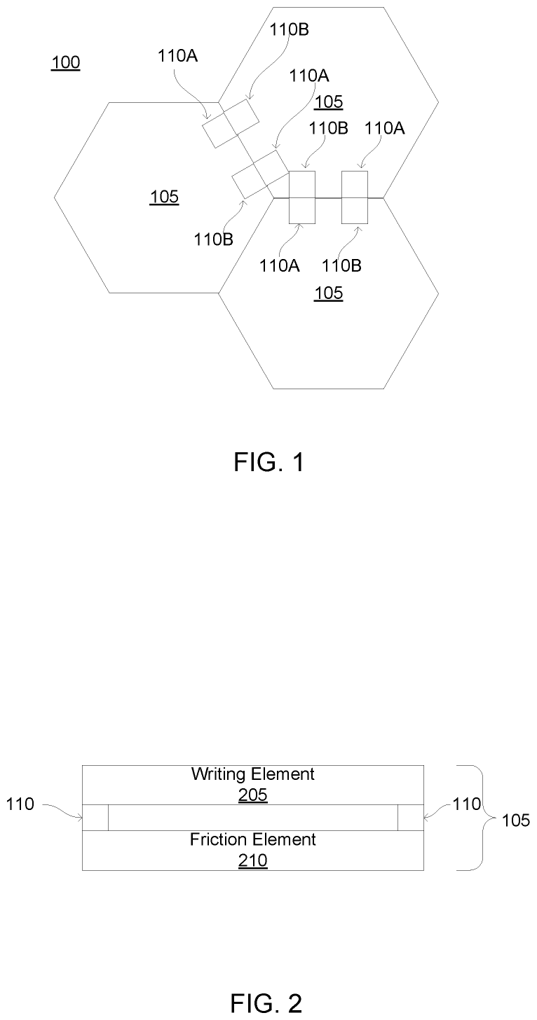

FIG. 1 is an example of a one embodiment of a writing surface 100 comprising a plurality of modular tiles 105. For purposes of illustration, FIG. 1 shows an example where each modular tile 105 is hexagonal. However, in other embodiments, each modular tile 105 is rectangular or has any suitable shape. In the example of FIG. 1, each modular tile 105 includes a plurality of magnets 110A, 110B positioned along various edges of a modular tile 105. To couple a modular tile 105 to another modular tile 105, magnets positioned along an edge of the modular tile 105 have alternating polarities proximate to the edge of the modular tile 105. For example, magnet 110A has its north pole nearest to the edge of the modular tile 105, while magnet 110B has its south pole nearest to the edge of the modular tile 105. In the preceding example, magnet 110A of a modular tile 105 is positioned adjacent to magnet 110B of another modular tile 105 and magnet 110B of the modular tile 105 is positioned adjacent to magnet 110A of the other modular tile 105 to couple modular tile 105 and the other modular tile 105. While FIG. 1 shows an embodiment where each modular tile 105 includes a plurality of magnets 110A, 110B, in other embodiments, each modular tile 105 includes any suitable number of magnets 110A, 110B. Additionally, in various embodiments, each modular tile includes an alternative coupling mechanism capable of removably coupling an edge of a modular tile 105 to an edge of an adjacent modular tile 105.

FIG. 2 is a side cross sectional view of one embodiment of a modular tile 105. In the example of FIG. 2, the modular tile 105 includes a writing element 205 and a friction element 210 opposite the writing element 205. In various embodiments, patterns may be etched into or overlaid on a surface of the writing element 205 or included in a layer of the writing element 205. The writing element 205 may have one or more colors in various embodiments. A color of a writing element 205 may be a property of a material used to create the writing element 205 or may be painted onto the writing element 205. In embodiments where the writing element 205 is painted, a clear surface is overlaid on a surface of the writing element 205 that is painted.

The friction element 210 includes a material having a coefficient of friction that resists movement of the modular tile 105 when the friction element 210 is contacting a surface on which the modular tile 105 is placed. For example, the friction element 210 has a layer of cork on a lower surface of the friction element 210 configured to contact a surface on which the modular tile 105 is placed. In some embodiments, the friction element 210 has a cushioned or soft material on the lower surface of the friction element 210 that is configured to contact a surface on which the modular tile 105 is placed, allowing the cushioned or soft material to protect the surface on which the modular tile 105 is placed. For example, the soft material on the lower surface of the friction element 210 configured to contact the surface is viscoelastic foam, polyurethane foam, or any other suitable type of foam. The friction element 210 may contact a horizontal surface or a vertical surface on which the modular tile is placed 105 in various embodiments.

In the embodiment shown by FIG. 2, the writing element 205 and the friction element 210 are separated by an intermediate layer, with one or more magnets 110, or other suitable coupling mechanisms, included in the intermediate layer. An electronic display coupled to one or more computing devices is included in the intermediate layer in various embodiments, allowing the modular tile 105 to display content (e.g., images, video) from a computing device below the writing element 205. Examples of the electronic display include a liquid crystal display (LCD), an organic light emitting diode (OLED) display, an active matrix liquid crystal display (AMLCD), or any other suitable device. In some embodiments, the electronic display is an electronic ink display. Additionally, when a modular tile 105 including an electronic display is coupled to another modular tile 105 including an electronic display, a computing device providing content to the electronic display adjusts a display area to display content using the electronic displays of the modular tiles 105 coupled together; hence, coupling a modular tile 105 including an electronic display to another electronic display including an electronic display results in electronic displays from both modular tiles 105 being used to display content. Hence, coupling multiple modular tiles 105 including electronic displays together increases a display area available for displaying content. In various embodiments where the intermediate layer includes an electronic display, the writing element 205 may be omitted. Alternatively, when the intermediate layer includes an electronic display, the writing element 205 may be replaced by a transparent or translucent coating over the electronic display. Coupling of modular tiles 105 including electronic displays is further described below in conjunction with FIG. 4.

In some embodiments, the intermediate layer includes an opening in which paper or other material may be inserted for presentation below the writing element 205. Additionally or alternatively, one or more lights may be included in the intermediate layer. The lights may be configured to receive input from a computing device, allowing the lights to be programmed.

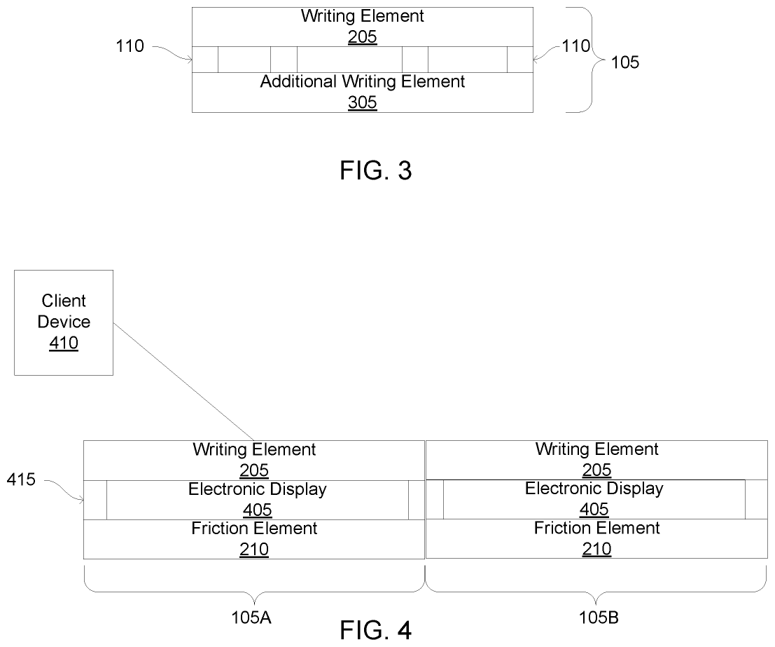

FIG. 3 shows an alternative embodiment of a modular tile 105 that includes a writing element 205 and an additional writing element 305 opposite the writing element 205. Hence, the modular tile 105 shown in FIG. 3 includes two writable surfaces. In the example of FIG. 3, the writing element 205 and the additional writing element 305 are separated by an intermediate layer including one or more magnets 110, or other connecting mechanism. The magnets 110 in the embodiment shown in FIG. 3 are positioned to allow the modular tile 105 to be coupled to a surface so that one of the writing element 205 or the additional writing element 305 contacts the surface, while the other of the writing element 205 and the additional writing element 305 is accessible for writing. The magnets 110 may be positioned in any suitable locations within the intermediate layer to allow the modular tile 105 to be coupled to a surface. In another embodiment, the modular tile 105 comprises a single layer including the writing element 205 and the additional writing element 305, with one or more magnets 110 embedded into the single layer.

Referring to FIG. 4, one embodiment of a system environment for modular tiles 105 including an electronic display 405 is shown. In the example of FIG. 4, the system environment includes two modular tiles 105A, 105B (also referred to individually and collectively using reference number 105) communicatively coupled to a client device 410. However, in other embodiments, the system environment may include any number of modular tiles 105.

The modular tiles 105A, 105B each include a wireless transceiver in the intermediate layer between a friction element 210 and a writing surface 205, as further described above in conjunction with FIGS. 1-3. Hence, the electronic display 405 of a modular tile 105 is opposite the friction element 210 of the modular tile 105. The wireless transceiver is configured to communicate with the client device 410 via one or more wireless communication protocols. For example, the wireless transceiver is configured to communicate with the client device 410 using BLUETOOTH®, 802.11, 802,16, or any other suitable wireless communication protocol.

The client device 410 is one or more computing devices capable of receiving user input as well as transmitting and/or receiving data. In one embodiment, the client device 410 is a conventional computer system, such as a desktop or a laptop computer. Alternatively, the client device 410 may be a device having computer functionality, such as a mobile telephone, a smartphone or another suitable device. In one embodiment, the client device 410 executes an application allowing a user of the client device 410 to interact with one or more modular tiles 105A, 105B that wirelessly communicate with the client device 410 the digital magazine server 410. For example, an application executing on the client device 410 communicates instructions or requests to display content, or to modify displayed content, to a modular tile 105. The client device 410 may also maintain one or more settings describing display of content from the client device 410 by modular tiles 105A, 105A when the modular tiles 105A, 105B are coupled to each other, as further described below.

While FIG. 4 shows an example where the modular tiles 105A, 105B include a writing element 205 positioned above the electronic display 405, in other embodiments a modular tile 105 replaces the writing element 205 with a transparent or translucent coating over the electronic display 405. Alternatively, a modular tile 105 omits the writing element 205 and comprises the electronic display 405 coupled to the friction element 210. In various embodiments, the electronic display 405 is a low power display such as a liquid crystal display (LCD), an organic light emitting diode (OLED) display, an active matrix liquid crystal display (AMLCD), or any other suitable device. The modular tile 105 includes light emitting diodes (LEDs) along the perimeter of the modular tile 105 in various embodiments; for example, the modular tile 105 includes one or more LEDs along one or more outer edges of the modular tile 105. An electronic display 405 of a modular tile 105 may be a touch sensitive display in some embodiments.

In various embodiments, each modular tile 105 includes a power supply that may be rechargeable. For example, a modular tile 105 includes a rechargeable battery and circuitry for connecting the rechargeable battery to a power supply via any suitable wired connection to charge the rechargeable battery. The rechargeable battery and circuitry are included between the electronic display 405 and the friction element 210 in various embodiments. The electronic display 405 is configured to be operable and to display content while the rechargeable battery (or other power supply) is charging in various embodiments. Additionally, connectors 415 included in a modular tile 105A include circuitry for coupling a power supply of the modular tile 105A or circuitry for charging the power supply of the modular tile 105A to an additional power supply included in another modular tile 105B having an additional connector 415 coupled to a connector 415 of the modular tile 105A. This allows charging to happen between multiple modular tiles 105A, 105B coupled to each other via connectors 415 when at least one of the modular tiles 105A, 105B coupled to each other is coupled to a power supply. Additionally, connectors 415 included in the modular tile 105 include circuitry for exchanging data, allowing modular tile 105A to receive content for display and communicate the content for display to another modular tile 105B coupled to the modular tile 105A by a connector 415 on the modular tile 105A being coupled to a connector on the modular tile 105B. Additionally, the connectors 415 included in modular tiles 105A, 105B include magnets in various embodiments to couple the modular tiles 105A, 105B to each other, as further described above in conjunction with FIG. 1, and to keep the modular tiles 105A, 105B in positions relative to each other when coupled.

When a modular tile 105A is coupled to another modular tile 105B, the overall display area for displaying content is increased to use the electronic displays 410 included in each of the modular tiles 105A, 105B. In the example of FIG. 4, coupling modular tile 105A to modular tile 105B enables display of content using both the electronic display 405 of modular tile 105A and the electronic display 405 of modular tile 105B. Hence, coupling modular tiles 105 to each other via the connectors 415 included in the modular tiles 105 increases an overall display area available for displaying content to a combination of the electronic displays 410 included in each of the modular tiles 105 coupled to each other. When modular tiles 105 are coupled to each other, the connection between the modular tiles 105 determines an orientation of the modular tiles 105 and relative to an originally connected modular tile 105.

An application executing on the client device 410 communicates with the modular tiles 105 to determine how content provided to one or more modular tiles 105 from the client device 410 are displayed by the electronic displays 405 of the modular tiles 105. For example, the application maintains one or more settings on the client device 410 describing how content from the client device 410 displayed by one or more modular tiles 105 is expanded or altered when one or more modular tiles 105 are coupled to the modular tiles 105 displaying content. As an example, if modular tile 105A and modular tile 105B are hexagonal and coupled to each other, a maximum height of the display area of the coupled modular tiles 105A, 105B when coupled to each other is a combined height of the modular tiles 105A, 105B coupled to each other and a width of the display area is determined by an aspect ratio of the display device of the client device 410. As another example, if modular tile 105A and modular tile 105B are hexagonal and coupled to each other, a maximum height of the display area of the coupled modular tiles 105A, 105B is a height of a single modular tile 105, with the width of the display area determined by an aspect ratio of the display device of the client device 410, with a portion of the content from the display device of the client device 410 cropped by the edges of the modular tiles 105A, 105B. As an additional example, if modular tile 105A and modular tile 105B are hexagonal and coupled to each other, a maximum width of the display area of the coupled modular tiles 105A, 105B is a combined width of the modular tiles 105A, 105B coupled to each other with the height of the display area of the coupled modular tiles 105A, 105B a height of a single modular tile 105A, 105B, where a portion of the content from the display device of the client device 410 cropped by the edges of the modular tiles 105A, 105B.

In some embodiments, different modular tiles 105A, 105B coupled to each other via connectors 415 receive content for display from different client devices 410. For example, modular tile 105A communicates with a client device 410 and displays content from the client device 410 via the electronic display 405 included in modular tile 105A, while modular tile 105B is coupled to modular tile 105A via connectors 415. In the preceding example, modular tile 105B receives content for display from a different client device 410 and displays the content from the different client device 410 via the electronic display 405 included in modular tile 105B. An application executing on the client device 410 (or the different client device 410) allows a user to select one or more of the modular tiles 105A, 105B as a display device for the client device 410 (or for the different client device 410). Settings maintained by the application may specify whether the client device 410 is authorized to override content being displayed on a modular tile 105 with content from the client device 410 in various embodiments. Different settings may be maintained for different modular tiles 105A, 105B in some embodiments, allowing the application to specify one or more modular tiles 105A, 105B that the client device 410, or that other client devices 410, may override content displayed by the specified modular tiles 105A, 105B with content from the client device 410 or from the other client devices 410. Similarly, one or more settings may specify specific modular tiles 105 that the client device 410 that another client device 410 cannot override content displayed by the specific modular tiles 105 with content from the client device 410 or from the other client devices 410

### Additional Considerations

The foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above disclosure.

Some portions of this description describe the embodiments of the invention in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention, which is set forth in the following claims.

What is claimed is:

1. A modular tile comprising:
a writing element on one side of the modular tile,
a friction element on another side of the modular tile opposite the writing element, the friction element comprising a material having a coefficient of friction that resists movement of the modular tile when the friction element contacts a surface on which the modular tile is placed, and
one or more coupling mechanisms positioned along one or more edges of the modular tile, a coupling mechanism configured to couple an edge of the modular tile to another coupling mechanism on an edge of an adjacent modular tile.

2. The modular tile of claim 1, wherein a coupling mechanism comprises a plurality of magnets having alternating polarities positioned proximate to the edge of the modular tile.

3. The modular tile of claim 2, wherein the plurality of magnets includes a magnet having a north pole nearest the edge of the modular tile and another adjacent magnet having a south pole nearest the edge of the modular tile.

4. The modular tile of claim 1, wherein the friction element comprises a layer of cork on a lower surface of the friction element configured to contact the surface on which the modular tile is placed.

5. The modular tile of claim 1, wherein the friction elements comprise a soft material on a lower surface of the friction element configured to contact the surface on which the modular tile is placed.

6. The modular tile of claim 1, wherein the writing element includes one or more patterns.

7. The modular tile of claim 1, where the writing element and the friction element are separated by an intermediate layer.

8. The modular tile of claim 7, wherein the one or more coupling mechanisms positioned along one or more edges of the modular tile are included in the intermediate layer between the writing element and the friction element.

9. The modular tile of claim 7, further comprising an electronic display included in the intermediate layer.

10. The modular tile of claim 7, further comprising one or more lights included in the intermediate layer.

11. The modular tile of claim 1, wherein the writing element and the friction element are hexagonal.

12. A modular tile comprising:
a wireless transceiver configured to communicate with a client device;
an electronic display configured to display content received from the client device via the wireless transceiver;
a friction element on another side of the modular tile opposite the electronic display, the friction element comprising a material having a coefficient of friction that resists movement of the modular tile when the friction element contacts a surface on which the modular tile is placed, and
one or more connectors positioned along one or more edges of the modular tile, a connector configured to couple an edge of the modular tile to another coupling mechanism on an edge of an adjacent modular tile, the connector including circuitry for exchanging content with an adjacent modular tile coupled to the modular tile by the connector for display on an additional electronic display of the adjacent modular tile.

13. The modular tile of claim 12, wherein the connector positioned along the edge of the modular tile includes one or more magnets proximate to the edge of the modular tile.

14. The modular tile of claim 12, wherein the modular tile further comprises a power supply.

15. The modular tile of claim 14, wherein the connector further includes circuitry for coupling the power supply to an additional power supply of the adjacent modular tile coupled to the modular tile by the connector.

16. The modular tile of claim 12, wherein one or more settings maintained on the client device determine presentation of content by the electronic display of the modular tile and the additional electronic display of the adjacent modular tile coupled to the modular tile by the connector.

17. The modular tile of claim 16, wherein a setting specifies a maximum height of content from the client device to the modular tile is a combined height of the modular tile and the adjacent modular tile coupled to the modular tile by the connector and specifies width of the content from the client device based on an aspect ratio of a display device of the client device.

18. The modular tile of claim 16, wherein a setting specifies a maximum height of content from the client device to the modular tile as a height of the modular tile and specifies width of the content from the client device based on an aspect ratio of a display device of the client device.

19. The modular tile of claim 16, wherein a setting specifies a maximum height of content from the client device to the modular tile is a combined height of the modular tile and the adjacent modular tile coupled to the modular tile by the connector and specifies a width of the content from the client device as a width of the modular tile.

20. The modular tile of claim 16, wherein the electronic display and the friction element are hexagonal.
